(19) United States
(12) Patent Application Publication
(10) Pub. No.: US 2019/0386257 A1
(43) Pub. Date: Dec. 19, 2019

(54) Depositor and print head for depositing a non-emissive layer of graded thickness

(71) Applicant: Universal Display Corporation, Ewing, NJ (US)

(72) Inventors: William E. QUINN, Whitehouse Station, NJ (US); Gregory MCGRAW, Yardley, PA (US); Gregg KOTTAS, Ewing, NJ (US); Xin XU, Plainsboro, NJ (US); Julia J. BROWN, Yardley, PA (US)

(21) Appl. No.: 16/430,486

(22) Filed: Jun. 4, 2019

Related U.S. Application Data
(60) Provisional application No. 62/686,124, filed on Jun. 18, 2018.

(51) Int. Cl. H01L 51/56; H01L 51/00

(52) U.S. Cl. CPC H01L 51/56; H01L 2251/558; H01L 2251/5346; H01L 51/0005

(57) ABSTRACT

Embodiments of the disclosed subject matter provide a depositor device having a first exhaust aperture and a second exhaust aperture, and a plurality of delivery apertures disposed between the first exhaust aperture and the second exhaust aperture. A first aperture of the plurality of delivery apertures may have a first length, and a second aperture of the plurality of delivery apertures may have a second length. The first length may be longer than the second length. The device may include a third aperture of the plurality of delivery apertures which may have a third length, where the second length may be longer that the third length. The plurality of delivery apertures of the device may include three or more delivery apertures having different lengths.

### CROSS-REFERENCE TO RELATED APPLICATIONS

This application claims priority to U.S. Patent Application Ser. No. 62/686,124, filed Jun. 18, 2018, the entire contents of which are incorporated herein by reference.

### FIELD

The present invention relates to depositors having delivery aperture groups. The deposition rates generated by each delivery aperture group may be different and may provide a printed film with graded thickness.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, a depositor device may include a first exhaust aperture and a second exhaust aperture, and a plurality of delivery apertures disposed between the first exhaust aperture and the second exhaust aperture. A first aperture of the plurality of delivery apertures may have a first length, and a second aperture of the plurality of delivery apertures may have a second length, where the first length may be longer than the second length.

The device may include a third aperture of the plurality of delivery apertures which may have a third length, where the second length may be longer that the third length. The plurality of delivery apertures of the device may include three or more delivery apertures having different lengths.

The device may include a first gas controller coupled to the first delivery aperture via a first manifold, a second gas controller coupled to the second delivery aperture via a second manifold, and a third gas controller coupled to the third delivery aperture via a third manifold.

The first aperture of the device may be configured to deposit a first segment of film with a first length of between 0.3 and 3 mm which corresponds to a transport layer in a first-emitting device. The second aperture may be configured to deposit a second segment of film with a second length approximately 75% that of the first length, which corresponds to a transport layer in a second-emitting device. The third aperture may be configured to deposit a third segment of film with a third length approximately 55% that of the first length which corresponds to a transport layer in a third-emitting device.

The plurality of delivery apertures of the device may be connected to a common delivery plenum. A delivery channel of the device may carry organic vapor entrained in a delivery gas stream to the plurality of delivery apertures.

The device may include a first exhaust channel and a second exhaust channel, where the first exhaust channel is coupled to the first exhaust aperture, and the second exhaust channel is coupled to the second exhaust aperture. The first exhaust aperture, the first exhaust channel, the second exhaust aperture and the second exhaust channel of the device may withdraw process gas and surplus organic vapor from a deposition zone.

The device may include a first transverse channel and a second transverse channel, where the first exhaust aperture and the second exhaust aperture may be disposed between the first transverse channel and the second transverse channel. The first transverse channel and the second transverse channel may provide uniform distribution of confinement gas from a chamber ambient along a length of the depositor device.

The first aperture of the device may be divided into two parts to form a first aperture group, and the second aperture may be divided into two parts to form a second aperture group. The first aperture group may have a first length and width, and the second aperture group may have a second length and width, where the first aperture thickness may be greater than the second aperture thickness. A third aperture of the plurality of delivery apertures of the device may have a third length, where the second length is longer that the third length, and where the third aperture is divided into two parts to form a third aperture group. The third aperture group may have a third thickness, where the second aperture thickness may be greater than the third aperture thickness.

According to an embodiment, a depositor device may include a first exhaust aperture and a second exhaust aperture, and a plurality of delivery apertures disposed between the first exhaust aperture and the second exhaust aperture, wherein the plurality of delivery apertures extend through a membrane having variable thickness. A first aperture of the plurality of delivery apertures may pass through a portion of the membrane having a first thickness, and a second aperture of the plurality of delivery apertures may pass through a portion of the membrane having a second thickness. The first thickness may be less than the second thickness.

The first aperture of the plurality of delivery apertures may have a first width, and the second aperture of the plurality of delivery apertures may have a second width. The first width may be wider than the second width. The device may include a third aperture of the plurality of delivery apertures having a third width, where the second width may be wider that the third width.

The first aperture may be configured to deposit a first segment of film with a first aperture width of between 5 μm and 30 μm, the second aperture may be configured to deposit a second segment of film with a second aperture width approximately 100% to 150% that of the first aperture width, and the third aperture may be configured to deposit a third segment of film with a third aperture width approximately 100% to 250% that of the first aperture width.

The first segment of film may be deposited over a first color filter, the second segment of film may be deposited over a second color filter, and the third segment of film may be disposed over a third color filter.

A first plurality of emissive layers may be deposited over the first segment of film, a second plurality of emissive layers may be deposited over the second segment of film, and a third plurality of emissive layers may be deposited over the third segment of film.

A first emissive layer may be deposited over the first segment of film, a second emissive layer may be deposited over the second segment of film, and a third emissive layer may be deposited over the third segment of film, where the first emissive layer and the second emissive layer may have the same range of emissive wavelengths.

The device may include a fourth delivery aperture configured to deposit a fourth segment of film, with a fourth aperture width that may be approximately 50% to 200% that of the first width. A first emissive layer may be deposited over the first segment of film, a second emissive layer may be deposited over the second segment of film, a third emissive layer may be deposited over the third segment of film, and a fourth emissive layer may be deposited over the fourth segment of film.

The plurality of delivery apertures may include three or more delivery apertures having different widths. There may be an increased amount of delivery gas that flows through the first aperture compared with the second aperture. In a multicolor pixel generated from monochromatic subpixels, the subpixels with a shorter emission wavelength may be wider and/or have a larger surface area than subpixels with longer emission wavelength.

According to an embodiment, a depositor device may include a first exhaust aperture and a second exhaust aperture, and a plurality of delivery aperture subunits disposed between the first exhaust aperture and the second exhaust aperture. A first subunit of the plurality of delivery aperture subunits may be configured to deposit a film of uniform thickness across a width of a pixel. A second subunit of the plurality of delivery aperture subunits may be configured to deposit a film of the same material as the first subunit of uniform thickness over the width of the two subpixels of the pixel with longer wavelength emission, while not adding to the material thickness over the subpixel with shorter wavelength emission. A third subunit of the plurality of delivery aperture subunits may be configured to deposit a film of uniform thickness of the subpixel with the longest wavelength emission, while leaving the other two subpixels unchanged.

The device may include a first gas controller coupled to a first delivery aperture of the first subunit via a first manifold, a second gas controller coupled to a second delivery aperture of the first subunit via a second manifold, and a third gas controller coupled to a third delivery aperture of the first subunit via a third manifold.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a pixel in a multicolor OLED (organic light emitting diode) array showing the different microcavity thicknesses present in the red, green, and blue subpixels.

FIG. 4A shows an aperture arrangement of a multi-delivery aperture group depositor configured to print a graded non-emissive layer on an OLED pixel according to an embodiment of the disclosed subject matter.

FIG. 4B shows a linear array of multiple delivery aperture group depositors configured to print a graded thickness film on a substrate according to an embodiment of the disclosed subject matter.

FIG. 5 shows a cross-section of a multiple delivery aperture group depositors positioned over a substrate according to an embodiment of the disclosed subject matter.

FIG. 6 shows stacked layer thicknesses in each subpixel of a multicolor OLED array according to an embodiment of the disclosed subject matter.

FIG. 7 shows a multi-delivery aperture group depositor with aperture groups configured to enhance deposition uniformity within each thickness gradation according to an embodiment of the disclosed subject matter.

FIG. 8 shows a simulation of a graded thickness thin film deposited by a multi-delivery aperture group depositor according to an embodiment of the disclosed subject matter.

FIGS. 9A-9B show alternate operations to control organic vapor flux within the area of a depositor using aperture array geometry according to embodiments of the disclosed subject matter.

FIG. 10 shows an alternate depositor design for depositing a thin film of graded thickness according to an embodiment of the disclosed subject matter.

FIG. 11 shows an array of depositors such that each aperture in a depositor has process gas supplied by a separate, independently tunable source according to an embodiment of the disclosed subject matter.

FIG. 12A shows an example pixel design similar to that shown in FIG. 6, but the individual red and green emissive layers are replaced with a single yellow emissive layer according to an embodiment of the disclosed subject matter.

FIG. 12B shows an example of a four-subpixel pixel design featuring red, green, sky-blue, and deep blue subpixels according to an embodiment of the disclosed subject matter.

FIG. 12C shows emissive layers may overlap in devices with a polychromatic emission spectrum to form a stacked device according to an embodiment of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

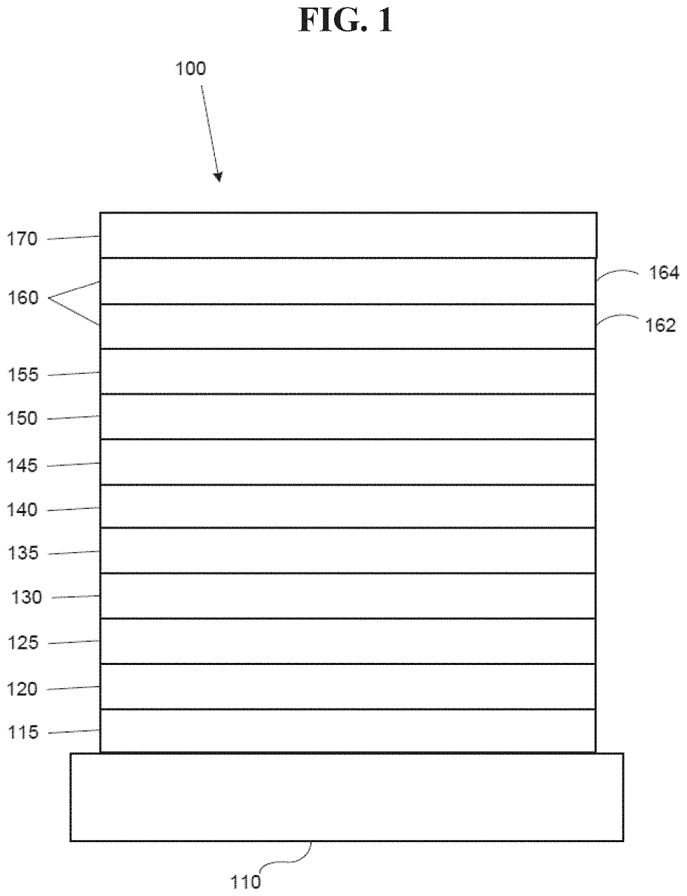

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

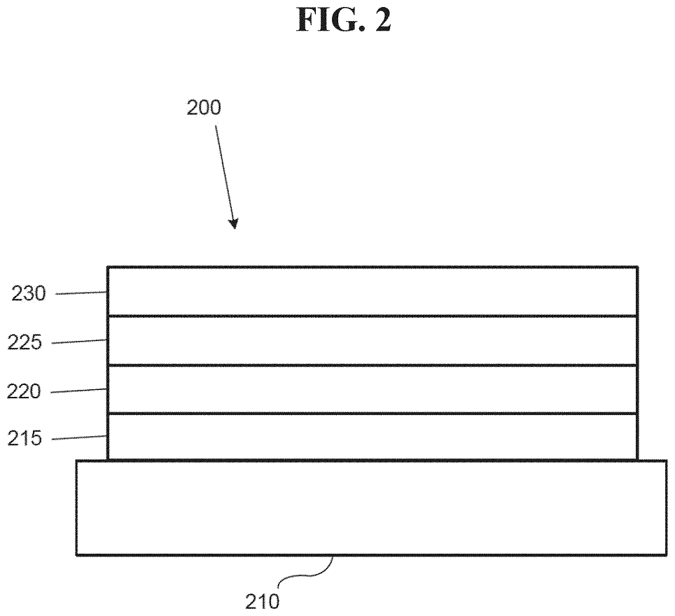

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

The thickness of the functional layers may be varied in different color subpixels of an OLED display to create a microcavity with optimal outcoupling at a desired emission wavelength from each subpixel type. Embodiments of the disclosed subject matter provide a modified Delivery-Exhaust-Confinement (DEC) type OVJP depositor to print a common charge transport layer of graded thickness over a pixel comprised of multiple monochromatic OLED subpixels of different color. The disclosed subject matter may provide delivery aperture groups fluidly coupled to a common delivery channel such that one or more of the aperture groups has a different hydrodynamic resistance from the others. The deposition rates generated by each delivery aperture group may be different, and may provide a printed film with graded thickness. This film may provide the different thicknesses of a charge transport layer desired for each subpixel. Depositors may be arranged in linear arrays for mass-printing.

Embodiments of the disclosed subject matter improve an OVJP process, such as disclosed in U.S. Patent Publn. No. 2014/065750, which may be used to deposit a non-emissive layer shared between different colored segments a multicolor OLED array so that the layer is of different thickness in different segments of the array. This may optimize the optical microcavity created by each segment to outcouple the peak emission wavelength of that segment.

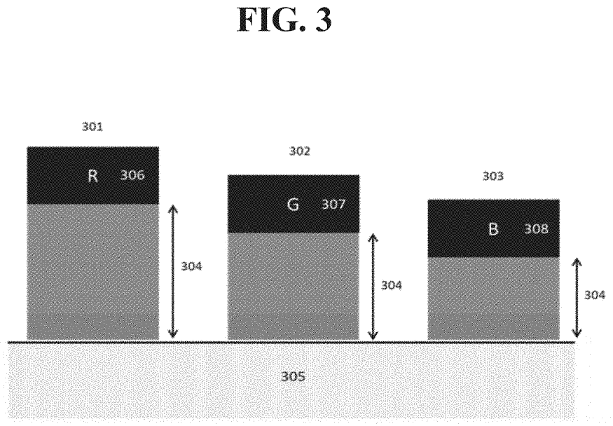

FIG. 3 shows a pixel in a multicolor OLED (organic light emitting diode) array showing the different microcavity thicknesses present in the red, green, and blue subpixels. As shown in FIG. 3, a pixel in a multicolor OLED array may include red emitting subpixel 301 having a red emissive layer 306, green emitting subpixel 302 having a green emissive layer 307, and blue emitting subpixel 303 having a blue emissive layer 308. The microcavity thickness 304 may be defined by the separation between the substrate 305 and a cathode in a bottom emitting device. The optimal thickness of the microcavity may vary linearly with the wavelength of light desired from each emissive segment. The thickness of a device optimized to emit red light at 600 nm may be 50% greater than a device optimized to emit blue at 450 nm. The thickness of a transparent oxide anode may be varied to optimize microcavity effects. However, the anode may need to be selectively thinned with photolithographically defined etching, which may be difficult to adapt for large scale production.

An alternate approach may be to adjust the thickness of one of the organic layers, usually the hole transport layer. The thickness of the hole transport layer may have little effect on the electronic properties of the device within certain limits, so its thickness may be selected to optimize microcavity effects. Deposition of organic thin films may be typically an additive process, so etching may not be used. A method of accurately depositing an organic thin film of varying thickness in specific locations on the substrate may be selected. Organic vapor jet printing is a spatially selective and scalable organic thin film deposition process that may be able to deposit a charge transport layer of graded thickness over the substrate of a large area multicolor OLED array. The near total isolation between print zones that is provided by OVJP may not be needed when printing hole transport material to generate devices with microcavities of different thicknesses. A few angstroms of cross-talk between zones of graded thickness may have negligible effect if the same material is printed in each zone. Embodiments of the disclosed subject matter may provide an OVJP depositor that is configured to deposit multiple thicknesses of a transport layer of the different color subpixels of a multicolor OLED array.

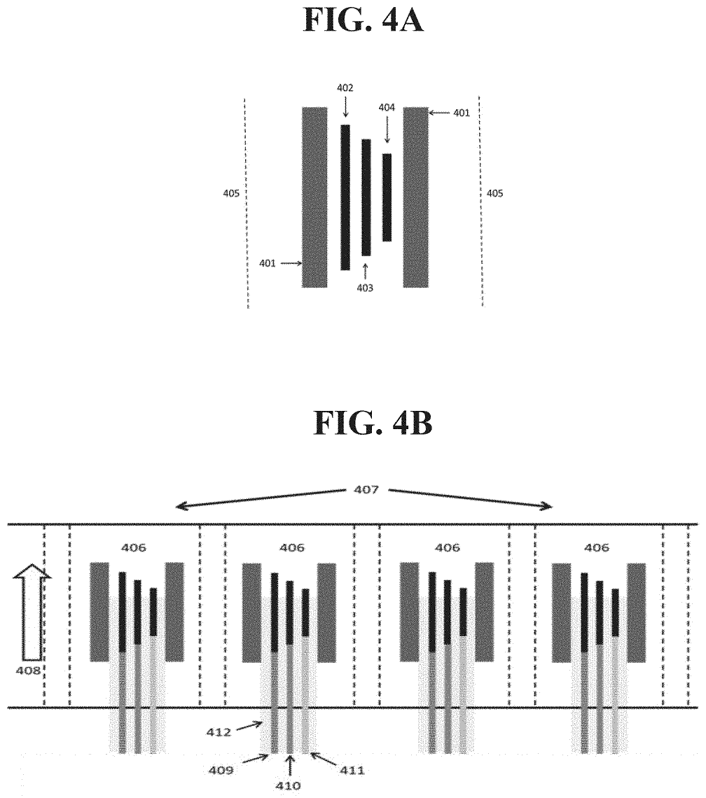

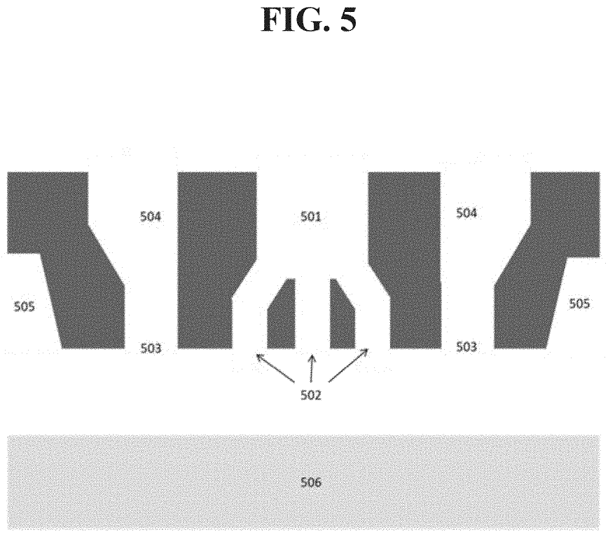

FIG. 4A shows the aperture arrangement of a multi-delivery aperture group depositor configured to print a graded non-emissive layer on an OLED pixel according to an embodiment of the disclosed subject matter. The aperture arrangement includes a plurality of delivery apertures between exhaust apertures 401. Each aperture may have a different length, which may correspond to the amount of deposition desired on a region of substrate disposed underneath the aperture arrangement. The longest aperture 402 may be configured to deposit the thickest segment of film. This segment may correspond to a transport layer in a red-emitting device. The intermediate length aperture 403 may be configured to deposit a transport layer in a green-emitting device. The shortest aperture 404 may be configured to deposit a transport layer that is thinner than that disposed by the intermediate length aperture 403, which may correspond to a blue-emitting device. The delivery apertures may be fluidly connected to a common delivery plenum. The amount of flow through each of the delivery aperture, and the deposition each produces, may depend on the length of each delivery aperture. Confinement gas may enter the depositor along its sides 405. Placing multiple delivery apertures next to each other without exhaust channels between them may permit the spacing of thickness gradations to be comparable to that of the separation between subpixels in an OLED display. Exhausts between each depositor may not be needed for overspray control because the material being deposited is common to all pixels, so they are omitted. Exhausts may be present on the outside of each depositor to remove excess organic material and promote inter-pixel uniformity when depositors are arrayed.

FIG. 4B shows a linear array of multiple delivery aperture group depositors configured to print a graded thickness film on a substrate according to an embodiment of the disclosed subject matter. The depositor may be configured to print an array of stripes of with the same material composition and different thicknesses as it moves over a substrate as shown in FIG. 4B. Depositors 406 may be arranged in a linear array 407 orthogonal to the print direction 408. Multiple ranks of depositors may be stacked along the print direction to increase pixel density, as well as reduce and/or eliminate the need for multiple passes of the print bar including the linear array 407. Thin film lines of greater thickness 409, intermediate thickness 410, and lesser thickness 411 may be printed by each depositor 406. The printed lines may be surrounded by a field of overspray material 412 extending between the exhausts.

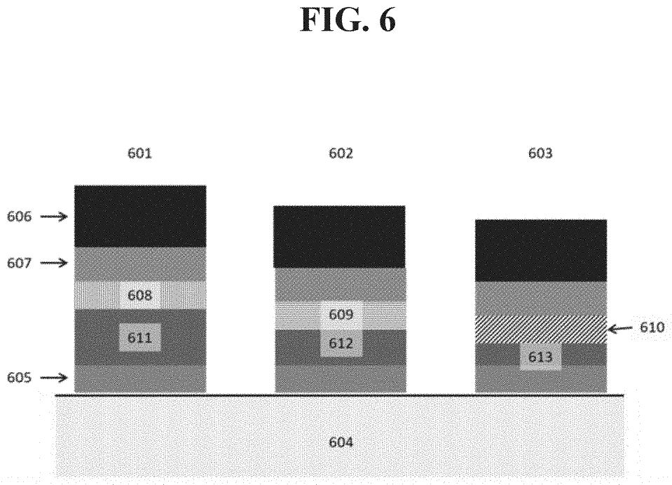

FIG. 5 shows a cross-section of a multiple delivery aperture group depositors positioned over a substrate according to an embodiment of the disclosed subject matter. A delivery channel 501 may be configured to carry organic vapor entrained in a delivery gas stream to three separate delivery apertures 502 at its terminus. Each of the delivery apertures 502 may have a different length. The exhaust apertures 503 may be positioned on either side of the delivery apertures 502, and open into exhaust channels 504 that withdraw process gas and surplus organic vapor from the deposition zone. The exhaust channels 504 may also connect to exhaust apertures of neighboring depositors. The depositors may be surrounded by transverse channels 505 etched into the depositor surface to provide a low impedance path for uniform distribution of confinement gas from the chamber ambient along the length of the depositor. The substrate 506 may be positioned underneath the depositor.

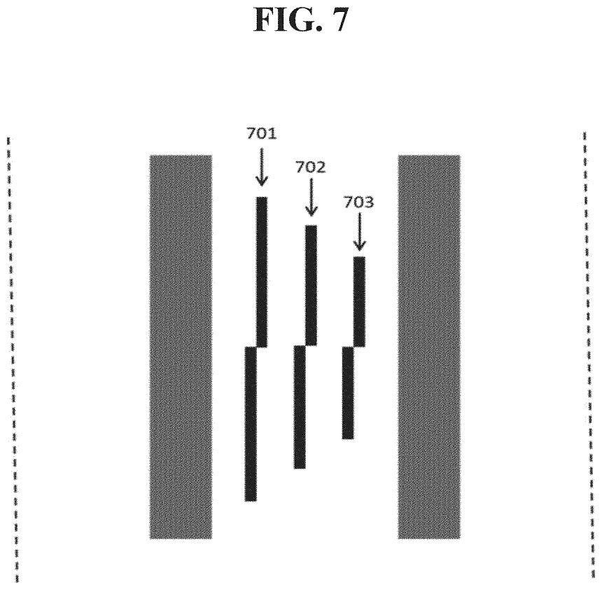

FIG. 6 shows stacked layer thicknesses in each subpixel of a multicolor OLED array according to an embodiment of the disclosed subject matter. As shown in FIG. 6, there may be microcavities of different thicknesses for each subpixel. The depositor may be configured to produce a device architecture that may include red emitting device 601, green emitting device 602, and/or blue emitting device 603 that may be deposited over top of a substrate 604. Each segment may include a thin film stack with a conductive metal oxide anode 605 at its base and a metal cathode 606 at its top, with an electron transport layer 607 disposed underneath it. Red emissive layer 608, green emissive layer 609, and/or blue emissive layer 610 may be disposed underneath the electron transport layer 607 in their corresponding segments. Between the emissive layers 608, 609, and 610 and an anode are hole transport layers (e.g., layers 611, 612, 613) of varying thickness. The thickest hole transport layer 611 may be located in the red emitting device 601, the layer of intermediate thickness hole transport layer 612 may be located in the green device 602, and the thinnest hole transport layer 613 may be located in the blue device 603. Note that banking and encapsulation structures that may be typically present in a device are omitted for clarity. In another example, the device may emit from a transparent surface on the cathode and the cavity-forming materials are deposited on top of the emissive layers.

Embodiments of the disclosed subject matter may minimize the non-uniformity within each thickness gradation, both to maintain an optimal microcavity effect and for consistent device electronic properties. The delivery aperture printing each gradation may be divided into a cluster of multiple apertures referred to as an aperture group. Apertures in a group may print the same feature with the same gradation of thickness, but the apertures may be sized and distributed to provide a uniform organic flux onto the substrate.

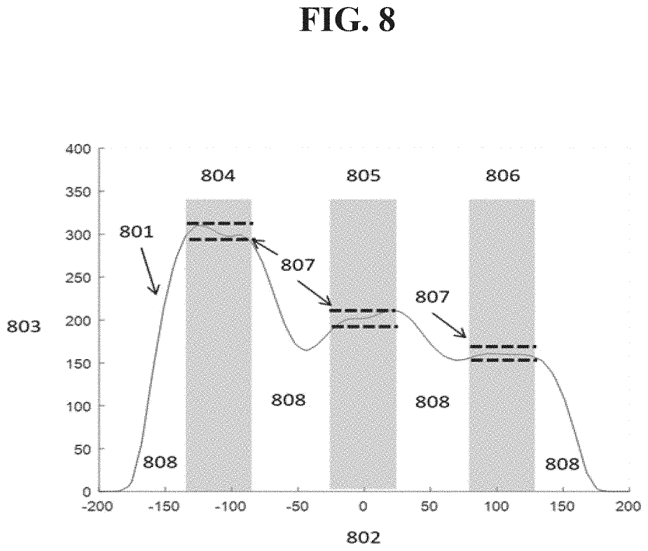

FIG. 7 shows a multi-delivery aperture group depositor with aperture groups configured to enhance deposition uniformity within each thickness gradation according to an embodiment of the disclosed subject matter. The aperture groups may be configured to print thin film gradations of a greater thickness 701, an intermediate thickness 702, and a lesser thickness 703. The thin film gradations may have offset front and rear portions in a manner similar to the split DEC OVJP depositors described in U.S. patent application Ser. No. 15/475,408 (now U.S. Patent Publn. No. 2017/0294615), which is incorporated by reference herein in its entirety. One or more delivery aperture configurations may be used to improve the uniformity of a printed feature within an active zone. The rate of deposition under each aperture group, and therefore the thickness of the thin film gradation printed by the apertures, may vary approximately linearly with the aperture's conductance to fluid flow. The thickness of film gradation printed by each aperture of the aperture group may be inversely proportional to its hydrodynamic resistance. The thickness of film gradation may vary linearly with the length of an aperture group if the apertures are long and narrow. The thickness may not necessarily scale linearly with the area of each aperture group, since conductance may scale as the square or cube of an aperture characteristic dimension.

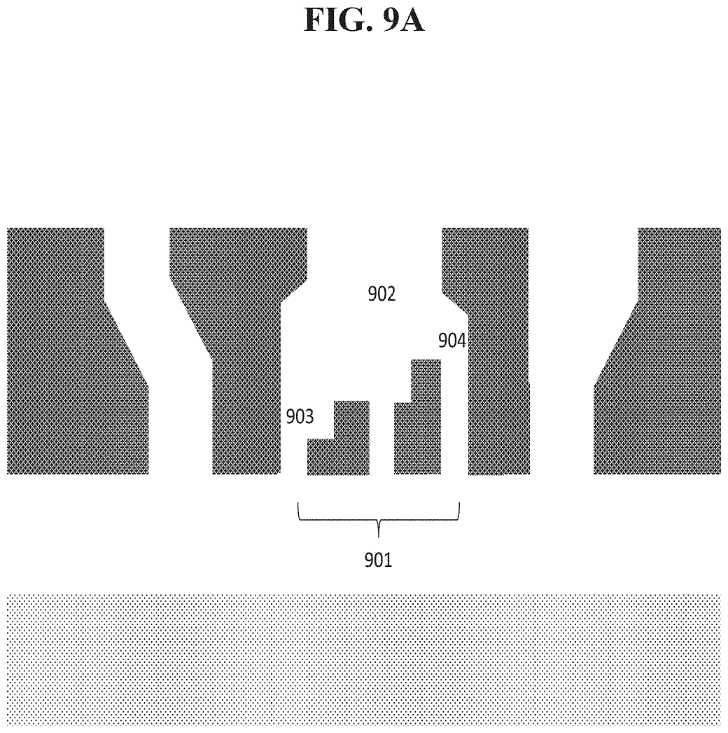

FIG. 8 shows a simulation of a graded thickness thin film deposited by a multi-delivery aperture group depositor according to an embodiment of the disclosed subject matter. A thickness profile 801 of a graded thickness thin film may deposited by a simulated print head. Position in the x direction along the substrate perpendicular to printing is indicated in microns on the horizontal axis 802. Film thickness is indicated in arbitrary units on the vertical axis 803. The 50 μm wide active areas of the red 804, green 805, and blue 806 subpixels within, for example, a typical 4K structure may be overlaid. Each of these regions may correspond to a plateau in the profile and a thickness grading in the printed film. Horizontal bars 807 may indicate an allowable uniformity budget of ±5% are placed around the profile peaks. Large overspray shoulders may be present between and around the peaks 808. The overspray shoulders may not create the concern they normally do in the OVJP process, because all material in a given transport layer may be of the same chemical species. That is, cross-contamination may be irrelevant as long as the overall thickness within the active area is as desired.

FIGS. 3-11 show embodiments for a typical RBG (red-green-blue) side-by-side device, but the examples do not limit the invention to this particular geometry. Alternate relative orientation of the pixels and alternative colors are possible (e.g., yellow subpixels, white subpixels, or the like). The total number of nozzles in the array between the exhaust may not be limited to three. The variable thickness layer may be any non-emissive organic layer within the device. The embodiments disclosed herein may be extended for other purposes, such as to reduce voltage in a stack.

As shown in connection with FIGS. 3-11, embodiments of the disclosed subject matter may provide a depositor device (e.g., linear array 407 having depositors 406 shown in FIG. 4B) that includes a first exhaust aperture and a second exhaust aperture (e.g., exhaust apertures 401 shown in FIG. 4A and/or exhaust apertures 503 shown in FIG. 5). A plurality of delivery apertures (e.g., depositors 406 shown in FIG. 4B and/or delivery apertures 502 show in FIG. 5) may be disposed between the first exhaust aperture and the second exhaust aperture. A first aperture of the plurality of delivery apertures may have a first length (e.g., longest aperture 402 shown in FIG. 4A) and a second aperture of the plurality of delivery apertures may have a second length (e.g., intermediate length aperture shown in FIG. 4A), where the first length may be longer than the second length. The device may include a third aperture of the plurality of delivery apertures which may have a third length (e.g., shortest aperture 404 shown in FIG. 4A), where the second length may be longer that the third length. The plurality of delivery apertures of the device may include three or more delivery apertures having different lengths (e.g., depositors 406 shown in FIG. 4B).

The first aperture of the device may be configured to deposit a first segment of film with a first length of between 0.3 and 3 mm which corresponds to a transport layer in a first-emitting device. The second aperture may be configured to deposit a second segment of film with a second length approximately 75% that of the first length, which corresponds to a transport layer in a second-emitting device. The third aperture may be configured to deposit a third segment of film with a third length approximately 55% that of the first length which corresponds to a transport layer in a third-emitting device. In some embodiments, the lengths of the first second and third apertures may be relative to each other, and the absolute lengths may depend on the configuration of each aperture. For example, the first aperture may have a length of x, the second aperture may have a length of 0.8x, and the third aperture may have a length of 0.6x. In some embodiments, a blue hole transport layer (HTL) may be 1000 Å (e.g., for the blue subpixel 603 shown in FIG. 6), a green HTL may be 1400 Å (e.g., for the green subpixel 602 shown in FIG. 6, and a red HTL may be 1850 Å (e.g., for the red subpixel 601 shown in FIG. 6).

In embodiments of the disclosed subject matter, the plurality of delivery apertures of the device may be connected to a common delivery plenum. A delivery channel of the device may carry organic vapor entrained in a delivery gas stream to the plurality of delivery apertures.

The device may include a first exhaust channel and a second exhaust channel, where the first exhaust channel is coupled to the first exhaust aperture (e.g., exhaust apertures 401 shown in FIG. 4A and/or exhaust apertures 503 shown in FIG. 5), and the second exhaust channel is coupled to the second exhaust aperture (e.g., exhaust apertures 401 shown in FIG. 4A and/or exhaust apertures 503 shown in FIG. 5). The first exhaust aperture, the first exhaust channel, the second exhaust aperture and the second exhaust channel of the device may withdraw process gas and surplus organic vapor from a deposition zone.

The device may include a first transverse channel and a second transverse channel (e.g., transverse channels 505 shown in FIG. 5), where the first exhaust aperture and the second exhaust aperture may be disposed between the first transverse channel and the second transverse channel (e.g., exhaust apertures 503 are disposed between the transverse channels 505, as shown in FIG. 5). The first transverse channel and the second transverse channel may provide uniform distribution of confinement gas from a chamber ambient along a length of the depositor device.

The first aperture of the device may be divided into two parts to form a first aperture group, and the second aperture may be divided into two parts to form a second aperture group (e.g., the aperture groups configured to print thin film gradations of a greater thickness 701, and an intermediate thickness 702, as shown in FIG. 7, which have offset front and rear portions). The first aperture group may have a first length and width and the second aperture group may have a second length and width, where the first aperture thickness may be greater than the second aperture thickness. A third aperture of the plurality of delivery apertures of the device may have a third length, where the second length is longer that the third length, and where the third aperture is divided into two parts to form a third aperture group (e.g., an aperture group configured to print a lesser thickness 703 shown in FIG. 7). The third aperture group may have a third thickness, where the second aperture thickness may be greater than the third aperture thickness.

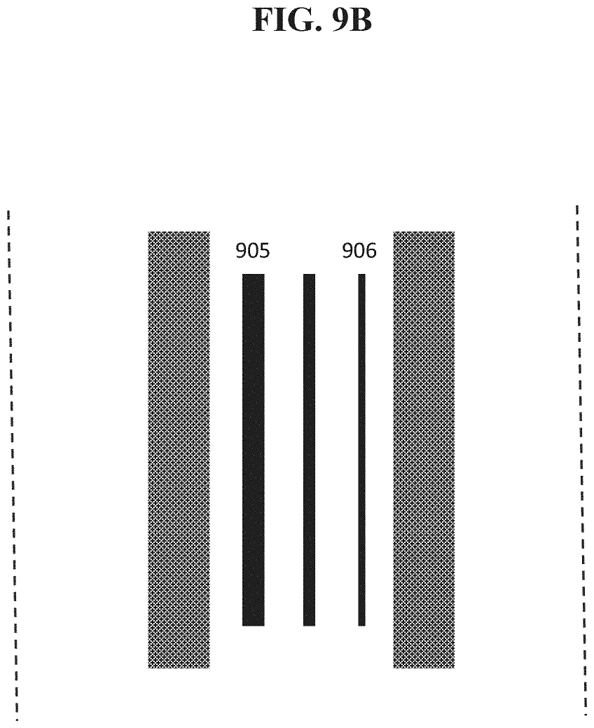

The distribution of organic flux from a depositor onto a substrate may be controlled, and the thickness profile of the layer of non-emissive organic material grown on a substrate. The conductivity of delivery apertures within an array may be varied to achieve a desired flux profile. Two operations by which this can be achieved are illustrated in FIGS. 9A-9B. The thickness of the material defining each aperture may be varied as shown by a depositor in cross section in FIG. 9A. Apertures that may extend through a membrane 901 of variable thickness are connected to a common plenum 902 behind the membrane 901. Delivery gas may flow through apertures 903 passing through thinner portions of the membrane 901, compared with apertures 904 passing through thicker portions of the membrane 901. This may provide a thicker deposit of material beneath the thinner membrane.

The width of apertures 904 may be varied instead of their length, as shown by the substrate side of the depositor depicted in FIG. 9B. Wider apertures may be less restrictive to flow than narrower ones, and a wide aperture 905 may permit more flow than a narrow aperture 906 when they are connected to a common plenum. This may result in increased film thickness under the wider aperture 905. In implementations of the disclosed subject matter, a depositor design may include actuators that can control the length, width, and/or thickness of each aperture within a depositor as needed during operation.

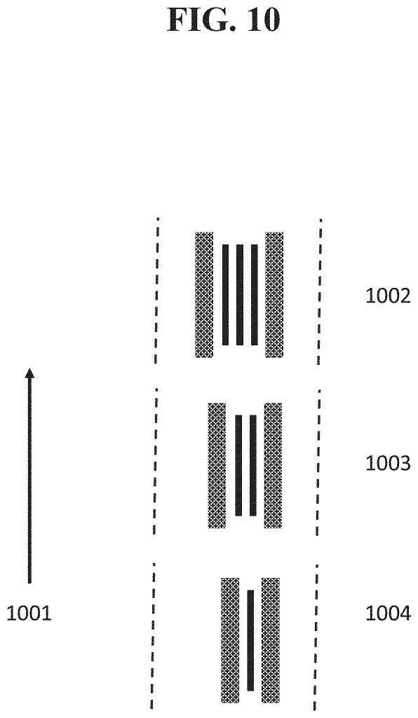

Apertures may be distributed along a printing direction 1001 as illustrated in FIG. 10. The depositor shown in FIG. 10 may include three subunits. A first depositor unit 1002 may print a film of uniform thickness across the width of the entire pixel. A second depositor unit 1003 may print a film of the same material of uniform thickness over the width of the two subpixels of the pixel with longer wavelength emission, while not adding to the material thickness over the subpixel with shorter wavelength emission. A third depositor unit 1004 may print a film of uniform thickness of the subpixel with the longest wavelength emission, while leaving the other two subpixels unchanged.

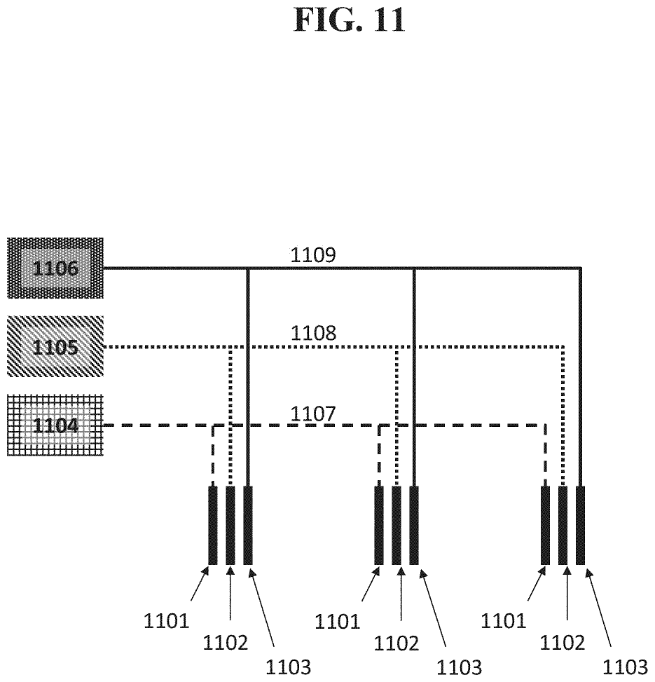

In some embodiments, such as shown in FIG. 11, delivery apertures 1101-1103 of a depositor may not be connected to a common plenum. Rather, the delivery apertures 1101-1103 may each be connected to a separate organic vapor source with a separate gas flow controller 1104-1106. This may allow flow through each portion of the depositor to be adjusted during operation, since the flows may be controlled independently of print head geometry. A print head may be constructed so that corresponding apertures from multiple depositors are fed from a common gas source. Each depositor, therefore, may be fed by multiple manifolds 1107-1109 while each manifold feeds multiple depositors. This may permit depositors to act as an array while still permitting control of material thickness within each depositor.

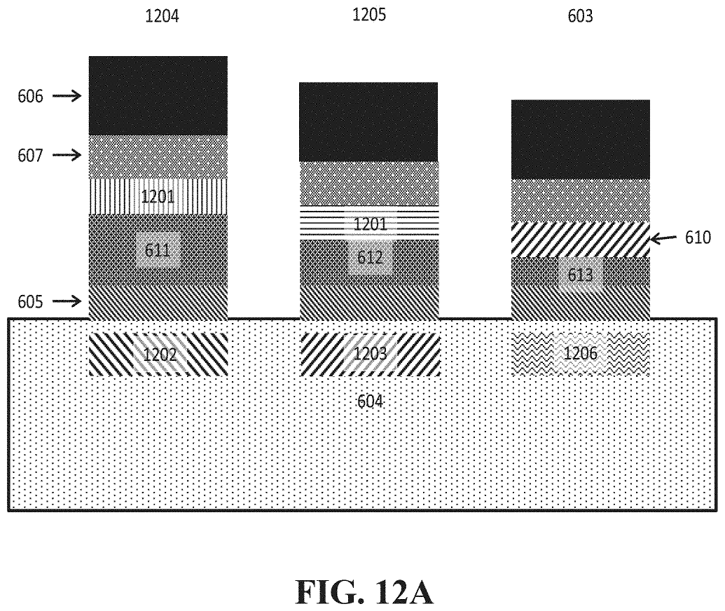

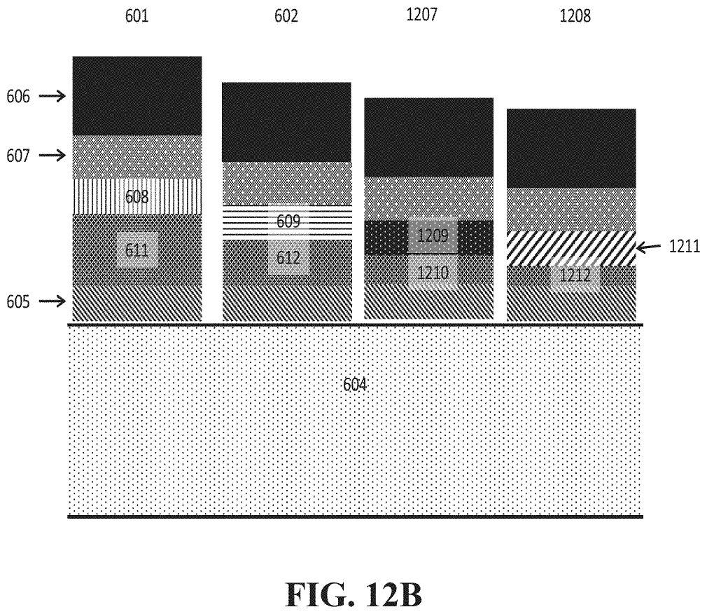

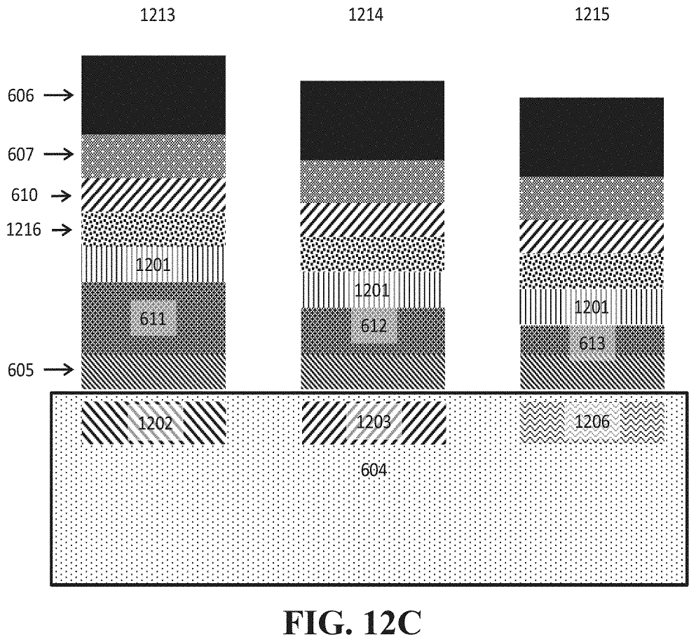

The emissive layer (EML) to be disposed may alternatively be an orange EML, a yellow EML, a blue-green EML, a sky-blue EML, or a violet EML. Such EMLs may include a single species of light emitting material, or they may include a mixture of light emitting materials. In some embodiments, an EML with a mixture of light emitting materials may emit white light. Examples of pixel designs with such EMLs are shown in FIGS. 12A-12C. Emissive layers that may not produce monochromatic red, green, and/or blue light may be used in display applications by superimposing the subpixel array in which they are contained with an array of color filters that selects the desired wavelength of emitted light from each subpixel. In this case, the thickness of the non-emissive layers of each subpixel may be selected to produce an optimal microcavity for light of the transmission wavelength of the color filter corresponding to that subpixel. The pixel design in FIG. 12A may be similar to that shown in FIG. 6, however the red emissive layer 608 and the green emissive layer 609 may be replaced with a single yellow EML 1201. Red 1202 and green 1203 color filters may be aligned with the two respective subpixels to select the red and/or green components of the light from the EML for transmission through the substrate. This display therefore has a red emitting subpixel 1204 and a green emitting subpixel 1205, despite the two subpixels sharing a common emissive layer. As described above, the thicknesses of the hole transport layers 611 and 612 may be selected to generate a microcavity that optimizes transmission of the color of light desired from each subpixel. They work in conjunction with the filters. A blue color filter 1206 may be aligned with a blue subpixel 1215 to narrow the emission spectrum of the blue subpixel 1215, if desired.

Display designs typically have red, green, and blue light emitted by separate subpixels, but some display architectures may include subpixels that emit light that is not of a primary additive color. Microcavities may be optimized for these subpixels as well. FIG. 12B shows an example of a four subpixel pixel design including red subpixel 601, green subpixel 602, sky-blue subpixel 1207, and deep blue subpixel 1208. The sky-blue subpixel may have a wavelength range between 460 nm and 500 nm. The sky-blue subpixel 1207 may have a sky-blue emissive layer 1209, and the thickness of the hole transport layer 1210 beneath the sky-blue emissive layer 1209 may be optimized to outcouple longer wavelengths blue light. Likewise, the deep blue subpixel 1208 may have a deep blue emissive layer 1211 and the thickness of the hole transport layer beneath 1212 may be optimized to outcouple shorter wavelengths of blue light. A pixel structure including two blue subpixels emitting light at different wavelengths is disclosed in U.S. Pat. No. 8,334,545, which is incorporated by reference herein in its entirety.

Emissive layers may overlap in devices with a polychromatic emission spectrum to form stacked devices such as in the example device shown in FIG. 12C. The red subpixel 1213, green subpixel 1214, and blue subpixel 1215 may have similar or identical layer structures above the hole transport layer 611, 612, 613. These subpixels may include a yellow emissive layer 1201, one or more interlayers 1216, and a blue emissive layer 610. Each subpixel may generate white light, and its color may be from the wavelength of light transmitted by the red color filter 1202, green color filter 1203, or blue color filter 1206 aligned with it. The thickness of the hole transport layer 611, 612, 613 of a subpixel 1213, 1214, 1215 may be optimized to produce microcavities that outcouple the wavelengths transmitted by the color filter 1202, 1203, 1206 in front of a respective subpixel 1213, 1214, 1215.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A depositor device comprising:
a first exhaust aperture and a second exhaust aperture; and
a plurality of delivery apertures disposed between the first exhaust aperture and the second exhaust aperture,
wherein a first aperture of the plurality of delivery apertures has a first length, and a second aperture of the plurality of delivery apertures has a second length, and
wherein the first length is longer than the second length.

2. The device of claim 1, further comprising:
a first gas controller coupled to the first delivery aperture via a first manifold, and
a second gas controller coupled to the second delivery aperture via a second manifold.

3. The device of claim 1, wherein a third aperture of the plurality of delivery apertures has a third length, and
wherein the second length is longer that the third length.

4. The device of claim 3, further comprising:
a third gas controller coupled to the third aperture via a third manifold.

5. The device of claim 3, wherein the first aperture is configured to deposit a first segment of film with a first length of between 0.3 and 3 mm which corresponds to a transport layer in a first-emitting device,
wherein the second aperture is configured to deposit a second segment of film with a second length approximately 75% that of the first length which corresponds to a transport layer in a second-emitting device, and
wherein the third aperture is configured to deposit a third segment of film with a third length approximately 55% that of the first length which corresponds to a transport layer in a third-emitting device.

6. (canceled)

7. The device of claim 1, wherein the plurality of delivery apertures are connected to a common delivery plenum.

8.-12. (canceled)

13. The device of claim 1, wherein the first aperture is divided into two parts to form a first aperture group, and
wherein the second aperture is divided into two parts to form a second aperture group.

14. The device of claim 13, wherein the first aperture group has a first length and width, and the second aperture group has a second length and width, and
wherein a first thickness of the first aperture is greater than a second thickness of the second aperture.

15. The device of claim 14, wherein a third aperture of the plurality of delivery apertures has a third length,
wherein the second length is longer that the third length, and
wherein the third aperture is divided into two parts to form a third aperture group.

16. The device of claim 15, wherein the third aperture has a third thickness, and wherein the second thickness of the second aperture is greater than the third thickness.

17. A depositor device comprising:
a first exhaust aperture and a second exhaust aperture; and
a plurality of delivery apertures disposed between the first exhaust aperture and the second exhaust aperture, wherein the plurality of delivery apertures extend through a membrane having variable thickness,
wherein a first aperture of the plurality of delivery apertures passes through a portion of the membrane having a has a first thickness, and a second aperture of the plurality of delivery apertures passes through a portion of the membrane having a second thickness, and
wherein the first thickness is less than the second thickness.

18. The device of claim 17, wherein the first aperture of the plurality of delivery apertures has a first width, and the second aperture of the plurality of delivery apertures has a second width, and wherein the first width is wider than the second width.

19. The device of claim 18, wherein a third aperture of the plurality of delivery apertures has a third width, and
wherein the second width is wider that the third width.

20. The device of claim 19, wherein the first aperture is configured to deposit a first segment of film with a first aperture width of between 10 μm to 50 μm,
wherein the second aperture is configured to deposit a second segment of film with a second aperture width approximately 100% to 150% that of the first width, and
wherein the third aperture is configured to deposit a third segment of film with a third aperture width approximately 100% to 200% that of the first width.

21. The device of claim 20, wherein the first segment of film is deposited over a first color filter, the second segment of film is deposited over a second color filter, and the third segment of film is disposed over a third color filter.

22. The device of claim 21, wherein a first plurality of emissive layers are deposited over the first segment of film, a second plurality of emissive layers are deposited over the second segment of film, and a third plurality of emissive layers are deposited over the third segment of film.

23. (canceled)

24. The device of claim 20, further comprising a fourth delivery aperture configured to deposit a fourth segment of film, with a fourth aperture width approximately 50% to 200% that of the first width.

25. The device of claim 24, wherein a first emissive layer is deposited over the first segment of film, a second emissive layer is deposited over the second segment of film, a third emissive layer is deposited over the third segment of film, and a fourth emissive layer is deposited over the fourth segment of film.

26.-27. (canceled)

28. A depositor device comprising:
a first exhaust aperture and a second exhaust aperture; and
a plurality of delivery aperture subunits disposed between the first exhaust aperture and the second exhaust aperture,
wherein a first subunit of the plurality of delivery aperture subunits is configured to deposit a film of uniform thickness across a width of a pixel,
wherein a second subunit of the plurality of delivery aperture subunits is configured to deposit a film of the same material as the first subunit of uniform thickness over the width of the two subpixels of the pixel with longer wavelength emission, while not adding to the material thickness over the subpixel with shorter wavelength emission, and
wherein a third subunit of the plurality of delivery aperture subunits is configured to deposit a film of uniform thickness of the subpixel with the longest wavelength emission, while leaving the other two subpixels unchanged.

29. The device of claim 28, further comprising:
a first gas controller coupled to a first delivery aperture of the first subunit via a first manifold;
a second gas controller coupled to a second delivery aperture of the first subunit via a second manifold; and
a third gas controller coupled to a third delivery aperture of the first subunit via a third manifold.
